(19) United States
(12) Patent Application Publication
(10) Pub. No.: US 2011/0076839 A1
(43) Pub. Date: Mar. 31, 2011

(54) MAKING FILMS COMPOSED OF SEMICONDUCTOR NANOCRYSTALS

(76) Inventors: Xiaofan Ren, Rochester, NY (US); Keith B. Kahen, Rochester, NY (US)

(21) Appl. No.: 12/568,980

(22) Filed: Sep. 29, 2009

(51) Int. Cl. H01L 21/20

(52) U.S. Cl. 438/478; 257/E21.09; 977/773

(57) ABSTRACT

A method of making a film of large II-VI nanocrystals, including: providing a mixture of column II, column VI chemical precursors, and coordinating solvents selected from amines, phosphines, phosphine oxides, esters, ethers, or combinations thereof by: injecting under heat a higher molar quantity of column II chemical precursor than column VI chemical precursor; and ii) increasing the ratio of column VI to column II chemical precursors during the course of the reaction while still heating the mixture until the molar ratio of column VI chemical precursor to column II chemical precursor is in a range of 1 to 10; heating the mixture to grow large nanocrystals functionalized with coordinating ligands; washing the grown nanocrystals to remove the unreacted precursors and excess coordinating solvents; and d) depositing the large II-VI nanocrystals on a substrate in order to form the film.

### CROSS-REFERENCE TO RELATED APPLICATIONS

Reference is made to commonly-assigned, co-pending U.S. patent application Ser. No. ______ (Kodak Docket 95537US01) filed herewith, entitled “Semiconductor Nanocrystal Film” by Ren et al., the disclosure of which is incorporated herein.

### FIELD OF THE INVENTION

The present invention relates to a method of making polycrystalline films composed of large-sized semiconductor nanocrystals

### BACKGROUND OF THE INVENTION

Charge transport layers containing n-type or p-type semiconductors can be used in making a variety of devices such as field effect transistors, bipolar transistors, p-n diodes, light emitting diodes (LEDs), lasers, sensors, solar cells and others. Most semiconductor devices in use today, both inorganic and organic, are in part or completely formed using expensive vacuum deposition processes. There are ongoing efforts to find a low cost manufacturing process, however, device performance has been inadequate for market needs. Therefore, there is a need for a low cost technique of forming high quality inorganic charge transport layers for use in semiconductor devices.

In general, both n-type and p-type materials can be referred to as charge transport materials, and the layers of a device containing such materials can be referred to as charge transport layers. An n-type material typically has an excess of conduction band electrons, and as such is also referred to as an electron transport material. Furthermore, an n-type semiconductor is a semiconductor in which electrical conduction is due chiefly to the movement of electrons. A p-type material typically has an excess of “holes”, and as such is also referred to as a hole transport material. Furthermore, a p-type semiconductor is a semiconductor in which electrical conduction is due chiefly to the movement of positive holes. The doping levels of the charge transport layers are typically set so that they are highest when the layers are in contact with metals (in order to assist in forming ohmic contacts). For the case of the layers in contact with the anode or cathode, the charge transport layers are also typically called contact layers.

Semiconductor diode devices have been in use since the late 1800s. Most modern diode technologies are based on semiconductor p-n junctions, or contact between p-type and n-type semiconductors. However, many types of electronics would benefit from lower cost charge transport layers. For example, in addition to the p/n junction, the junction could be a p/p junction, an n/n junction, a p/i junction (where i refers to an intrinsic semiconductor), an n/i junction, an i/i junction, or the like. A junction may also be a semiconductor/semiconductor junction, a semiconductor/metal junction (a Schottky junction), or a semiconductor/insulator junction. The junction may also be a junction of two different semiconductor materials (a heterojunction), a doped semiconductor to a doped or an undoped semiconductor, or a junction between regions having different dopant concentrations. The junction may also be a defected region to a perfect single crystal, an amorphous region to a crystal, a crystal to another crystal, an amorphous region to another amorphous region, a defected region to another defected region, an amorphous region to a defected region, or the like.

In the field of photovoltaic devices, current devices employ thin layers of semiconductor material, e.g., crystalline silicon, gallium arsenide, or the like, incorporating a p-n junction to convert solar energy to direct current. While these devices are useful in certain applications, their efficiency has been somewhat limited, yielding conversion efficiencies, e.g., solar power to electrical power, of typically marginally better than 10-20%. Although efficiencies of these devices have been improving through costly improvements to device structure, the relative inefficiency of these devices, combined with their relatively high cost, have combined to inhibit the widespread adoption of solar electricity in the consumer markets. Instead, such systems have been primarily used where conventionally generated electricity is unavailable, or where costs associated with bringing conventionally generated electricity, to a location where it is needed, more closely match the costs of photovoltaic systems.

Despite the issues with current photovoltaic technology, there is still a desire and a need to expand usage of solar electricity. In particular, there is generally a need for an improved photovoltaic cell that has one or more of: increased energy conversion efficiency, decreased manufacturing costs, greater flexibility or reasonable durability or longevity. In fact, as disclosed in U.S. Pat. No. 7,089,832, Scher et al. disclose the use of coatable nanoparticles in a polymer binder for use in photovoltaic devices. However, the performance of these devices was not reported, and the conductivity of such a mixed photoactive layer should be low due to the high resistivity of the polymeric binder. An example of the performance of devices with these hybrid absorber layers is an efficiency of ˜1.5% under AM 1.5 excitation (J. Liu et al., JACS 126, 6550 (2004]). Recently, an all inorganic solution processed solar cell was formed from CdSe and CdTe quantum rod nanoparticles, but again the efficiency was very low at 3% even after sintering the films at 400° C. for 15 minutes (I. Gur et., Science 310, 462 [2005]). A large part of the low efficiency was undoubtedly due to the films being insulators (even after sintering) due to the lack of doping. For both CdTe and CuIn₁₋ₓGaₓSe_{2-y}S (CIGSS) solar cells, the window layer is typically n-CdS (N. G. Dhere et al., J. Vac. Sci. Technol. A23, 1208 [2005]). Both doped and undoped forms of CdS have been used in the devices and a preferred deposition technique has been chemical bath deposition (CBD). Even though a solution processed technique, CBD involves dunking the entire wafer into a bath, which can be acidic or basic, for periods up to hours. In addition, the process is inefficient with respect to usage of its starting materials.

FIG. 1 gives a schematic of a typical prior art LED device 105 that incorporates charge transport layers. All of the device layers are deposited on the substrate 100. Above the substrate are the p-contact layer 110, the p-transport layer 120, the intrinsic emitter layer 130, the n-transport layer 140, and the n-contact layer 150. The anode 160 makes ohmic contact with the p-contact layer 110, while the cathode 170 makes ohmic contact with the n-contact layer 150. As is well-known in the art, LED structures typically contain doped n- and p-type transport layers, and more heavily doped n- and p-type contact layers. They serve a few different purposes. Forming ohmic contacts to semiconductors is simpler if the semiconductors are doped. Since the emitter layer is typically intrinsic or lightly doped, it is much simpler to make ohmic contacts to the doped transport layers. As a result of surface plasmon effects (K. B. Kahen, Appl. Phys. Lett. 78, 1649 [2001]), having metal layers adjacent to emitter layers results in a loss emitter efficiency. Consequently, it is advantageous to space the emitter layers from the metal contacts by sufficiently thick (at least 150 nm) transport layers. Next it is advantageous to employ transport layers that not only can easily inject charge into the emitter layer, but also prevent the carriers from leaking back out of the emitter layer. As a consequence, the transport layers will have the largest bandgaps of the device layers. As is well known in the art, highly doping wide bandgap semiconductors is difficult as a result of self-compensation effects. Consequently, forming ohmic contacts to these layers can prove to be difficult. As a result, it is adventitious to add contact layers to the device whose bandgap is smaller than that of the transport layers. Beyond these advantages, doping the transport layers also reduces ohmic heating effects (which can be highly important for laser devices) and leads to larger separations of the n- and p-quasi Fermi levels (which also aids laser, pin diode, and photovoltaic devices). The above discussion illustrates that having the ability to create doped transport layers results in numerous advantages for many semiconductor electronic devices.

LED devices have been made since the early 1960's and currently are manufactured for usage in a wide range of consumer and commercial applications. The layers comprising the LEDs are conventionally based on crystalline semiconductor materials that require ultra-high vacuum techniques for their growth, such as, molecular organic chemical vapor deposition (MOCVD). In addition, the layers typically need to be grown on nearly lattice-matched substrates in order to form defect-free layers. These crystalline-based inorganic LEDs have the advantages of high brightness (due to layers with high conductivities), long lifetimes, good environmental stability, and good external quantum efficiencies. The high conductivities of the transport layers result from high mobilities (due to the crystalline nature of the films) and the ability to readily dope crystalline layers with donors and acceptors. The usage of crystalline semiconductor layers that results in all of these advantages also leads to a number of disadvantages. The dominant ones are high manufacturing costs, difficulty in combining multi-color output from the same chip, and the need for high cost and rigid substrates.

A way for forming low cost LEDs began in the 80's with the introduction of organic light emitting diodes (OLED) (Tang et al, Appl. Phys. Lett. 51, 913 [1987]). The transport layers for these devices are highly resistive (10⁸ ohm-cm) in comparison with those used in crystalline LEDs. Recent attempts at doping these layers (J. Huang et al., Appl. Phys. Lett. 80, 139 [2002]) have resulted in layer resistivities in the 10⁴-10⁶ ohm-cm range. However, many of these dopants are unstable and the resistivities are many orders of magnitude higher than crystalline LED values of ˜0.1 ohm-cm. The result of employing resistive layers is that one suffers from ohmic heating effects; it is difficult to make ohmic contacts and since the drive current of the device is limited, so is the overall brightness of the device.

The above examples illustrate that higher performance semiconductor devices can be created from crystalline semiconductor materials, but with the drawback of high manufacturing costs. Attempts to reduce the manufacturing costs by employing organic materials result in lower performance devices whose specifications sometimes fall significantly short of market requirements (e.g., organic-based photovoltaics). Two approaches to lower the cost of crystalline semiconductor materials are to employ either amorphous or polycrystalline inorganic semiconductor materials; however, both of these approaches have well-known drawbacks. Taking the case of devices formed from amorphous Si, both thin-film transistor and photovoltaic (PV) devices have significantly reduced performance due to low mobilities (and the Staebler-Wronski effect for PVs). The performance of polycrystalline-based devices is improved with devices formed from processes, such as, sputtering and CBD. Sputtering is a higher cost, vacuum-based deposition process and CBD, though chemically based, has long deposition times and is inefficient in its usage of starting materials, as stated previously.

Another way for creating low cost semiconductor devices is to form the layers from inorganic semiconductor nanoparticles. To obtain the full advantage of these crystalline particles for usage in semiconductor transport layers, the nanoparticles should both be doped (to increase their intrinsic carrier concentration) and devoid of organic ligands on their surface (which impede charge transport). In spite of a plethora of reports about doping nanoparticles to modify their emission and magnetic characteristics (S. C. Erwin et al., Nature 436, 91 [2005]), there has been very limited research devoted to modifying the nanoparticle's carrier concentration (D. Yu et al., Science 300, 1277 [2003]). In the work of Yu et al., even though they doped nanoparticle films, it was done by adding potassium through a high vacuum, post deposition, vacuum evaporation process. In general, even if nanoparticles are stripped of their insulating organic ligands by an annealing process, without added impurities atoms to modify the donor or acceptor concentrations, the resulting nanoparticles have limited conductivities (I. Gur et., Science 310, 462 [2005]).

Doping, the intentional introduction of impurities into a material, is fundamental to controlling the properties of bulk semiconductors. When a macroscopic semiconductor crystal is grown under thermal equilibrium conditions, impurity atoms can be incorporated up to their solid solubility limit. This has simulated similar efforts to dope semiconductor nanocrystals. Despite some success, many of these efforts have failed. For example, Mn can be incorporated into nanocrystals of ZnS and CdSe, but not into CdSe, despite comparable bulk solubility of near 50%. These difficulties are often attributed to “self-purification”, an allegedly intrinsic mechanism where impurities are expelled due to highly stable surfaces of nanocrystals with sizes in the “quantum confinement” region. Another problem specifically associated with carrier doping is that the doping levels are typically in the 1 part in 10⁴-10⁵ range, while a 4 nm spherical nanoparticle only contains on the order of 1000 atoms (C. B. Murray et al., JACS 115, 8706 [1993]). As a result, many of the nanoparticles would not contain a dopant atom. This situation causes problems since if a large fraction of the nanoparticles is undoped, then these nanoparticles would be highly resistive which would result in the device layer being highly resistive. One way to circumvent this problem is doping large-sized nanocrystals such that each particle would contain the impurity atoms and, thus, would show reasonable conductance properties. This has been reduced to practice by doping nanowires that have diameters of ˜3 nm and lengths of ˜1 μm (K. B. Kahen, U.S. Pat. No. 7,494,903). After sintering these doped wires together at high temperatures, the resistivity of the as-made film dropped to 1.8×10⁵ ohm-cm, as compared to >9.5×10⁶ ohm-cm for undoped films. Even though this research successfully demonstrated the viability of in situ carrier doping of nanocrystals with a sufficiently large size, the reported film resistivity is still too high for usage as transporting layers in device applications. The high resistivity suggests that incorporation of dopant atoms to the wires may not be very efficient despite the expanded length. A possible scenario is that due to the small diameters of these wires, the majority of the dopant atoms reside near the surface of the wires. During the process whereby the wires are isolated and purified, and later subjected to ligand exchange, the dopant atoms are removed from the surface, hence leading to inefficient doping.

### SUMMARY OF THE INVENTION

In accordance with the present invention, there is provided a method of making a film of large II-VI nanocrystals, comprising:

a) providing a mixture of column II, column VI chemical precursors, and coordinating solvents selected from amines, phosphines, phosphine oxides, esters, ethers, or combinations thereof; by: P i) injecting under heat a higher molar quantity of column II chemical precursor than column VI chemical precursor; and

ii) increasing the ratio of column VI to column II chemical precursors during the course of the reaction while still heating the mixture until the molar ratio of column VI chemical precursor to column II chemical precursor is in a range of 1 to 10.

b) heating the mixture to grow large nanocrystals functionalized with coordinating ligands;

c) washing the grown nanocrystals to remove the unreacted precursors and excess coordinating solvents; and d) depositing the large II-VI nanocrystals on a substrate in order to form the film.

### ADVANTAGES

It is an advantage of the present invention to enable a method of forming polycrystalline films of II-VI nanocrystals having an aspect ratio less than 3:1 and a diameter greater than 10 nanometers. In accordance with the present invention, it has been determined that the use of large amount of fatty acids or phosphonic acids prevents the formation of organic-free films comprising large II-VI nanocrystals. By using the above-described coordinating solvents, the problem has been overcome and films of large II-VI nanocrystals with less than 5% by volume of organic material can now be made. Large-sized II-VI nanocrystals with high crystallinity are formed by injecting under heat a lower molar quantity of column VI chemical precursors than column II chemical precursors; then gradually increasing the ratio of column VI to column II chemical precursors during the course of the reaction. The resulting nanocrystals can be cleanly isolated from the reaction mixture. As such, polycrystalline films of large II-VI nanocrystals with less than 5% by volume of organic material are formed. The large size and low aspect ratio of the nanocrystals facilitates formation of doped semiconductor nanoparticles with modified carrier concentration. The presence of low volumes of organic materials in the films formed from these in-situ doped nanoparticles enables enhanced carrier transport in the films. By incorporating in-situ doped inorganic nanoparticles into the transport layers of electronic devices, one can produce the devices at low cost while still maintaining good device performance. In addition, the device layers can be deposited by low cost processes, such as, drop casting, spin coating, or inkjetting, and the resulting nanoparticle-based device can also be formed on a range of substrates.

### BRIEF DESCRIPTION OF THE DRAWINGS

FIG. 1 shows a side-view schematic of a prior art inorganic light emitting device;

FIG. 2 shows a schematic of a colloidal inorganic nanocrystals;

FIG. 3 shows a representation of a Transmission Electron Microscopy (TEM) of the large-sized CdSe nanocrystals; and

FIG. 4 shows a representation of a photograph of a drop-casted film composed of the large-sized CdSe nanocrystals functionalized with low boiling point ligand pyridine.

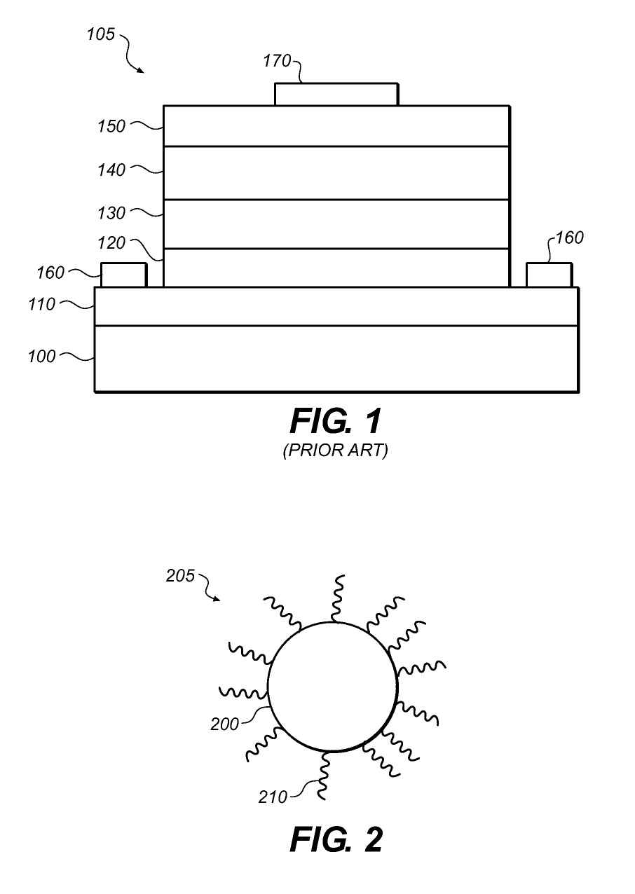

### DETAILED DESCRIPTION OF THE INVENTION

It is desirable to form devices that not only have good performance, but also are low cost and can be deposited on arbitrary substrates. Using colloidal-based nanocrystals as the building blocks for semiconductor electronic devices would result in devices that confer these advantages as long as the layers can be properly doped. A typical colloidal inorganic nanocrystals 205 is shown in FIG. 2. In the figure, the inorganic nanocrystals 205 is composed of a semiconductor core 200, on whose surface is bonded organic ligands 210. The organic ligands 110 give stability to the resulting colloidal dispersion (the inorganic nanocrystals 205 and an appropriate solvent). Even though the inorganic nanocrystals 205 shown in FIG. 2 is spherical in shape, nanocrystals can be synthesized to be shapes ranging from quantum rods and wires, to tetrapods and other multiply connected nanocrystals.

Semiconductor films can be doped by a number of ways. Some of these are extrinsic processes, namely, the doping occurs after the materials comprising the layer have been grown or synthesized. For example, extrinsic donors and acceptors can be introduced into a layer by ion implantation and by diffusion processes (P. J. George et al., Appl. Phys. Lett. 66, 3624 [1995]). For the diffusion processes, the source for the dopant materials can be a solid source (metal on the layer surface), a liquid source (containing appropriate metal ions), and a vapor source (e.g., closed tube diffusions containing a subliming metallic source). Even though the semiconductor industry has a long history of implementing these extrinsic doping procedures, they involve extra processing steps, such as, removing the solid diffusion source once the diffusion process is complete. Another way for generating donors and acceptors is by creation of native defects. In compound semiconductors, they can be generated by annealing the layers under appropriate overpressure conditions. In general this method is not preferred. The preferred doping approach is called in-situ doping that occurs when donors or acceptors are introduced into the materials during their synthesis. For crystalline semiconductors, in-situ doping has been highly successful, especially using the ultra high vacuum processes such as MOCVD and molecular beam epitaxy (MBE).

Adapting in-situ doping to inorganic nanocrystals 205 has a number of challenging issues associated with it, as discussed in the Background section. The strategy for dealing with these issues was to use nanocrystals that not only have large sizes but also are substantially spherical, because a substantially spherical nanocrystal with a diameter larger than 10 nm is more like a fragment of the bulk lattice containing more than 20,000 atoms. These features minimize “self-purification” associated small-sized nanocrystals and, ensure that each nanocrystal would contain sufficient impurity atoms embedded far away from the surface and, thus would show reasonable conductance properties. Furthermore, in order to obtain high conductivity semiconductor films, the synthetic procedure has to be carefully designed such that after the formation of the nanocrystals, all organic material, including the coordinating ligands bonded on the surface of the nanocrystals, excess of free organic ligands, solvents and by-products, need to be removed easily.

Typically, colloidal II-IV nanoparticles reported in the literature have sizes in the range of 2-6 nm which is the size range where quantum confinement effect becomes important and room-temperature emissions can be observed. As a result, reports on making II-IV nanocrystals having sizes larger than 10 nm are scarce. In the work of Murray et al., CdSe nanocrystals as large as 11.5 nm have been prepared by injecting a mixture of dimethylcadmium and TOPSe into a hot solution of TOPO and TOP(C. B. Murray, et al., JACS, 115, 8706 [1993]). However, the long hours it takes to reach the size of 11.5 nm, together with the usage of the extremely toxic cadmium precursor CdMe₂, makes this preparation method impractical from a manufacture point of view. In addition, large-sized CdSe nanocrystals synthesized by this method using multiple injections are generally limited to around 11 nm and often with a significant aspect ratio. More recently, Peng's group investigated different kinds of safe, common, and low-cost organic compounds to be used as coordinating solvents/ligands for the synthesis of high quality II-VI nanocrystals (L. Qu, et al., Nano Letters, 1, 333 [2001]). Their work shows that among all of the solvent/ligand system tested, fatty acids are excellent candidates for synthesizing relatively large-sized CdSe nanocrystals. Using stearic acid as an example, without secondary injection, this solvent system (50_{wt}% of fatty acid and 50_{wt}% of TOPO) yields CdSe nanocrystals in a very broad size range from about 2 nm to 25 nm. Moreover, the shape of the CdSe nanocrystals with a diameter up to 25 nm can be purposely controlled to dot-shape. The ability of fatty acids to enable synthesis of large nanocrystals is believed to come about from the fast growth rates of nanocrystals in this solvent system. This reaction has been successfully reproduced and large-sized CdSe nanocrystals were indeed obtained. However, during the process of isolation and purification of these dots, it was found that large amount of white organic impurities was formed during the reaction, which precipitate out of the reaction mixture with the nanocrystals. These white organic impurities have very low solubility in common organic solvents at room temperatures. By repeating the process of heating the nanocrystals/white organics mixture in methanol to the boiling temperature and centrifugation while the mixture is still hot for a number of times, the white organics were only partially removed, and a significant amount of nanocrystals were also lost during the process. The remaining white impurities further hindered the following ligand exchange process. As a result, the nanocrystal films drop-casted on glass appeared highly non-uniform, full of pin-holes and large clumps of materials.

In another work of Peng, et al., rice-shaped CdSe nanocrystals with a size of up to 30 nm along the long axis and 8-10 nm along the short axis are reported (Z. A. Peng et al., JACS, 124, 3343 [2002]). These nanocrystals are formed by using a less reactive cadmium precursor, cadmium phosphonic acid complexes, in the presence of large excess of starting materials and with regular replenish of the monomer concentration. The same experiment was performed and the formation of rice-shaped CdSe nanocrystals was observed, even though the sizes were not as large as reported. The as-formed nanocrystals could be isolated and purified. However, replacing the phosphonic acid bonded on the surface of the nanocrystals with low boiling point pyridine at temperatures near 100° C. failed, most likely due to the strong bonding between cadmium and phosphonic acid. Higher boiling point pyridine analogues, such as 3-methylpyridine, were also tested so that the ligand exchange reaction could be done at higher temperatures, but to no avail. Due to the presence of long-chain phosphonic acid, the nanocrystal films drop-casted on glass appeared again highly non-uniform, full of pin-holes and large clumps of materials.

Accordingly, it is an object of the invention to overcome the limitations of the prior art and to provide nanocrystals that not only meet the size requirement but also lead to continuous and smooth films of nanocrystals with low volumes of organics present.

This object is solved by a process of producing II-VI nanocrystals having the features of the respective independent claims. The process comprises:

a) providing a mixture of column II, column VI chemical precursors, and coordinating solvents selected from amines, phosphines, phosphine oxides, esters, ethers, or combinations thereof by:

i) heating a reaction mixture containing the column VI chemical precursor, in a form suitable for the generation of a nanocrystal, and a suitable coordinating solvent or solvent mixture to a suitable temperature T1; injecting at this temperature a higher molar quantity of the column II chemical precursor than column VI chemical precursor, in a form suitable for the generation of a nanocrystal; heating the reaction mixture at a suitable temperature T2, and ii) adding to the reaction mixture at temperature T2 or another suitable temperature T3 a sufficient quantity of column VI chemical precursor; increasing the ratio of column VI to column II chemical precursors during the course of the reaction until the molar ratio of column VI chemical precursor to column II chemical precursor is in a suitable range. Besides one-time injection, multiple injections of column VI chemical precursor, or a mixture of column VI and column II chemical precursors with a higher content of column VI precursor, can be adopted as deemed suitable;

b) heating the mixture to grow large nanocrystals functionalized with coordinating ligands

c) washing the grown nanocrystals in suitable solvents to remove the unreacted chemical precursors, by-products, and excess coordinating solvents;

d) exchanging the coordinating ligands with low-boiling-point coordinating ligands by dispersing the grown nanocrystals bonded with the coordinating ligands in a suitable low-boiling-point coordinating ligands, and heating the mixture;

e) forming a dispersion of organic solvents and nanocrystals functionalized with low-boiling-point coordinating ligands;

f) forming a film of the dispersion of nanocrystals made in last step by spin casting, drop casting, inkjetting, or other suitable processes;

g) heating the film to remove the low-boiling-point coordinating ligands at a suitable temperature, or in multiple steps where sequentially each step has a greater temperature than the prior step.

The synthesis of II-VI nanocrystals is based on the pyrolysis of organometallic reagents by injections into a hot coordinating solvent. This provides temporally discrete nucleation and permits controlled growth of macroscopic quantities of nanocrystals.

The initial column II to column VI precursor ratio has been found by the inventors and other groups as an important factor for determining the size of the resulting nanocrystals. It has been speculated that the more column II precursor existed in the initial stage, the slower the nucleation process occur, and the less nuclei are generated in the nucleation stage. Consequently, the remaining monomer concentration after the nucleation stage remains high, which accelerates the growth rate, and results in large-sized nanocrystals.

Different from the traditional multiple injections whereby a certain ratio of injected column II to column VI precursors are maintained throughout the reaction, the one adopted here either only replenish the column VI precursor at certain time intervals, or replenish both the column VI and column II precursors but with a higher content of column VI precursor. After the primary injection, the system starts with a large excess of column II precursor. The following secondary injections increased the total amount of column VI precursor gradually, which eventually converted the reaction system from a column II precursor excess system to a column VI precursor excess system. A column VI precursor excess system is believed to yield II-VI nanocrystals with high crystallinity and a surface with fewer defects. Therefore, the synthetic approach described herein is able to generate large-sized and high-quality II-VI nanocrystals.

In step a ii) of the process, the molar ratio of column VI chemical precursor to column II chemical precursor is in a range of 1 to 10, and more preferably in a range of 2 to 5.

The preferred temperature range for T1, T2 and T3 is between 250° C. to 400° C., and more preferably between 290° C. to 360° C. It is preferable that both T2 and T3 are equal to or lower than T1. However, it should be noted that if a solvent with lower boiling point is used, the inventive process disclosed here can also be carried out at lower temperature, as long as the desired nanocrystals are obtained.

In the so-called II-VI nanocrystals of the present invention, the column II element comprised herein is preferably independently selected from the group consisting of Zn, Cd and Hg. The column VI element comprised herein is preferably independently selected from the group consisting of S, Se and Te. Thus, all combinations of these elements are within the scope of the invention, which include binary, ternary, or quarternary compositions. Preferred embodiments are nanocrystals having the composition CdSe, ZnSe, ZnTe, CdS, ZnS, CdTe, HgS, ZnₓCd₁₋ₓSe, ZnₓCd₁₋ₓS, ZnₓCd₁₋ₓTe, HgₓCd₁₋ₓSe, ZnSeₓS_{1-x, ZnSe}ₓTe_{1-x, CdSe}ₓS₁₋ₓ, CdSeₓTe₁₋ₓ, ZnₓCd₁₋ₓSe_{y}Te_{1-y} or ZnₓCd₁₋ₓSe_{y}S_{1-y}.

The column II and column VI precursors are known to the skilled person. Examples of the numerous suitable forms of the precursors include organometallic compounds, for example, alkylated compounds such as dimethylzinc (ZnMe₂), diethylzinc (ZnEt₂), dimethylcadmium (CdMe₂) or dimethylmercury (HgMe₂). Other suitable precursors are the metal salts of long chain alkyl carboxylic acid (with about 10 to 22 chain carbon atoms, which can be saturated or unsaturated) such as stearic acid, palmitic acid or oleic acid. Complexes of oxides of the column II elements with such long chain alkyl carboxylic acids are also suitable precursors. These precursors can be synthesized and used as stock solutions or made in situ. Other examples of column II cation precursors are CdO, CdCO₃, Cd(Ac)₂, CdCl₂, Cd(NO₃)₂, CdSO₄, ZnO, ZnCO₃, Zn(Ac)₂, Hg₂O, HgCO₃ and Hg(Ac)₂.

It is preferred that the column VI precursor used for the synthesis of large-sized II-VI nanocrystals is a material selected from a group consisting of sulfur (S), selenium (Se), and tellurium (Te). Some examples of corresponding anion precursors are bis(trimethylsilyl)sulfide, tri-n-alkylphosphine sulfide, hydrogen sulfide, tri-n-alkenylphosphine sulfide, alkylamino sulfide, alkenylamino sulfide, tri-n-alkylphosphine selenide, alkenylamino selenide, tri-n-alkylamino selenide, tri-n-alkenylphosphine selenide, tri-n-alkylphosphine telluride, alkenylamino telluride, tri-n-alkylamino telluride, tri-n-alkenylphosphine telluride. Other appropriate anion precursors can also be used as is well known in the art. These precursors can be synthesized and used as stock solutions or made in situ. For in situ formation of the presurcor, S, Se, or Te can also be used as the element form.

A wealth of suitable high boiling point compounds exist that can be used both as reaction media and, more importantly, as coordination ligands to stabilize the metal ion after it is formed from its precursor at high temperatures. They also aid in controlling particle growth and impart colloidal properties to the nanocrystals. Among the different types of coordination ligands that can be used are alkyl phosphine, alkyl phosphine oxide, alkyl phosphate, alkyl amine, alkyl phosphonic acid, and fatty acids. The alkyl chain of the coordination ligand is preferably a hydrocarbon chain of length greater than 4 carbon atoms and less than 30 carbon atoms, which can be saturated, unsaturated, or oligomeric in nature. It can also have aromatic groups in its structure.

Specific examples of suitable coordination ligands and ligand mixtures include, but are not limited to, trioctylphosphine, tributylphosphine, tri(dodecyl)phosphine, trioctylphosphine oxide, tributylphosphite, trioctyldecyl phosphate, trilauryl phosphate, tris(tridecyl)phosphate, triisodecyl phosphate, bis(2-ethylhexyl)phosphate, tris(tridecyl)phosphate, hexadecylamine, oleylamone, octadecylamine, bis(2-ethylhexyl)amine, octylaime, dioctylaime, cyclododecylamine, n, n-dimethyltetradecylamine, n, n-dimethyldodecylamine, phenylphosphonic acid, hexyl phosphonic acid, tetradecyl phosphonic acid, octylphosphonic acid, octadecyl phosphonic acid, propylphosphonic acid, aminohexyl phosphonic acid, oleic acid, stearic acid, myristic acid, palmitic acid, lauric acid, and decanoic acid.

Further, it can be used by diluting the coordinating ligand with at least one solvent selected from a group including 1-nonadecene, 1-octadecene, cis-2-methyl-7-octadecene, 1-heptadecene, 1-pentadecene, 1-tetradecenedioctylether, dodecyl ether, hexadecyl ether or the like.

It should be noted here that the use of large amounts of fatty acids or phosphonic acids prevents the formation of films of large II-VI nanocrystals without substantial amount of organics present. Therefore, the weight percentage of fatty acids or phosphonic acids in the total ligand/solvent mixture should be less than 10%, and preferably less than 5%.

Having grown the II-VI nanocrystals 205, it is then necessary to create a layer composed of them. As is well known in the art, three low cost techniques for forming nanocrystal films are depositing the colloidal dispersion of II-VI nanocrystals 205 by drop casting, spin coating and inkjetting. Common solvents for drop casting colloidal nanocrystals 205 are a 9:1 mixture of hexane:octane (C. B. Murray et al., Annu Rev. Mater. Sci. 30, 545 [2000]). The organic ligands 210 need to be chosen such that the colloidal nanocrystals 205 are soluble in non-polar solvents. As such, organic ligands with hydrocarbon-based tails are good choices, such as, the alkylamines. Using well-known procedures in the art, the ligands coming from the growth procedure (trioctylphosphine oxide, for example) can be exchanged for the organic ligand 210 of choice (C. B. Murray et al., Annu Rev. Mater. Sci. 30, 545 [2000]). When spin coating a colloidal dispersion of nanocrystals 205, the requirements of the solvents are that they easily spread on the deposition surface and the solvents evaporate at a moderate rate during the spinning process. It was found that alchohol-based polar solvents are a good choice; for example, combining a low boiling point alcohol, such as, ethanol, with higher boiling point alcohols, such as, a butanol-hexanol mixture or 1-propanol, results in good film formation. Correspondingly, ligand exchange can be used to attach an organic ligand 210 (to the nanoparticles 205) whose tail is soluble in polar solvents; pyridine is an example of a suitable ligand. After formation of the nanocrystal films, it is preferred that the organic ligands 210 attached to the colloidal nanoparticles 205 evaporate as a result of annealing the films in an inert atmosphere. By choosing the organic ligands 210 to have a low boiling point (less than 200° C.), they can be made to evaporate from the film during an annealing process (C. B. Murray et al., Annu Rev. Mater. Sci. 30, 545 [2000]) where the anneal temperature is below 220° C., or in multiple steps where sequentially each step has a greater temperature than the prior step. Consequently, for films formed by drop casting with non-polar solvents, shorter chained primary amines, such as, hexylamine are preferred; for films formed by spin coating with polar solvents, pyridine is a preferred ligand.

In order to enable the nanocrystals to be dispersed in various solvents, the nanocrystal surface needs to be functionalized with the appropriate organic ligands. The procedure for exchanging the synthesis ligands with the appropriate surface functionalization ligands is well known in the art. For enabling the dispersion of the nanocrystals in various solvents, appropriate surface functionalization organic ligands can be represented by Xx(Y)nZz, wherein X is, for example, SH, NH₂, P, P═O, CSSH, or aromatic heterocycles; Z is, for example, OH, NH₂, NH₃⁺, COOH, or PO₃²⁻; and (Y)n is, for example, a material mainly having a structure of a saturated or unsaturated hydrocarbon chain, or an aryl that connects X and Y. It is preferable that a particularly suitable material is any material selected from a group including pyridine, pyridine derivatives, mercapto-alkyl acid, mercapto-alkenyl acid, mercapto-alkyl amine, mercapto-alkenyl amine, mercapto-alkyl alcohol, mercapto-alkenyl alcohol, dihydrolipolic acid, alkylamino acid, alkenyl amino acid, aminoalkylcarboic acid, hydroxyalkylcarboic acid or hydroxyalkenylcarboic acid, but it is not limited to these materials as is well known in the art.

The solvent used for making the dispersion of the nanocrystals functionalized with low-boiling-point coordinating ligands include, but not limited to, toluene, hexane, heptane, octane, ethanol, methanol, propanol, pyridine, pyridine derivatives, or combinations thereof.

After removing the low boiling point organic ligands, the resulting film comprises semiconductor nanocrystals having an aspect ratio less than 3:1 and diameter greater than 10 nm, wherein the film has less than 5% by volume of organic materials. The diameter of the semiconductor nanocrystals comprising the film can also be greater than 12 nm, or even 14 nm. In one embodiment of the film, the nanocrystals comprising the film have less than 5% by area functionalized with organic ligands. In another embodiment of the film, the nanocrystals comprising the film are substantially spherical in shape.

It is within the scope of the present invention that the film includes semiconductor nanocrystals wherein the semiconductor is selected from type II-VI, III-V, IV-VI, or IV semiconductor materials. The semiconductor nanocrystals can be either doped or undoped by impurities. Specific type IV semiconductors are Si, Ge, and Sn. Specific type III-V semiconductors are AN, AlP, AlAs, and AlSb; GaN, GaP, GaAs, and GaSb; and InN, InP, InAs, and InSb. Specific II-VI semiconductors are ZnS, ZnSe, and ZnTe; CdS, CdSe, and CdTe, HgS, HgSe, and HgTe. Specific IV-VI semiconductors are PbS, PbSe, and PbTe. These various semiconductor materials can be doped by the following materials. For type IV semiconductors, the dopant atoms can be selected from group III or V materials. For type III-V semiconductors, the dopant atoms can be selected from group Ha, IIb, IV, or VI materials. For type II-VI semiconductors, the dopant atoms can be selected from group Ia, Ib, III, V, or VII materials. For type IV-VI semiconductors, the dopant atoms can be selected from group III, V, or VII materials.

In one embodiment, the semiconductor material is type II-VI, or I11-V semiconductor material having binary, ternary, or quaternary compositions. In another embodiment, the semiconductor material is type II-VI semiconductor material selected from but not limited to CdSe, ZnSe, ZnTe, CdS, ZnS, CdTe, HgS, ZnₓCd₁₋ₓSe, ZnₓCd₁₋ₓS, ZnₓCd₁₋ₓTe, HgₓCd₁₋ₓSe, ZnSeₓS₁₋ₓ, ZnSeₓTe₁₋ₓ, ZnₓCd₁₋ₓSe_{y}Te_{1-y} or ZnₓCd₁₋ₓSe_{y}S_{1-y}.

It is also within the scope of the present invention that the film is formed by a mixture of large-sized nanocrystals having different compositions, or a mixture of large-sized and small-sized nanocrystals having the same, or different compositions.

### Example 1

Polycrystalline films of nanocrystals having an aspect ratio less than 3:1 and a diameter greater than 10 nanometers were formed on glass substrates. The test system was CdSe. The cadmium precursor is cadmium acetate and the Se precursor is TOPSe. The coordinating solvent for the growth is a mixture of trioctylphosphine oxide (TOPO) hexadecylamine (HDA), and trioctylphosphine (TOP), which are degassed at 190° C., 100° C., and 190° C., respectively, for 60 minutes prior to their usage. In a small vial inside of a dry box, 0.23 g (1 mmol) of cadmium acetate is added to 3 ml TOP. After gently heating this mixture under constant spinning, the solution goes clear in 5-10 minutes. At the same time, a mixture of 6 ml of degassed TOPO and 3 ml of degassed HDA is placed in a three-neck flask and placed on a Schlenk line. At room temperature, the contents are subjected to three cycles of evacuation, and are then degassed at 100° C. for 30 minutes followed by argon refilling. Then 0.5 ml TOPSe solution prepared by dissolving 0.7896 g (10 mmol) Se in 10 ml Top in the dry box is added into the solvent mixture by injection from a syringe. After the injection, the flask contents are taken up to 310° C. and the CdAc2 solution loaded in a syringe is injected into the three-neck flask. The contents of the flask turn deep brown within seconds of the injection. After the injection, the reaction mixture is stirred at 290° C. for 15 min. Afterwards, while keeping the temperature at 290° C., 1.5 ml of the TOPSe solution (1 M) is dripped into the reaction flask at a rate of 10 ml/hr and the reaction mixture continue to stir at 290° C. till the total growth time reaches 1 hour. The reaction is then stopped by removing the heating source.

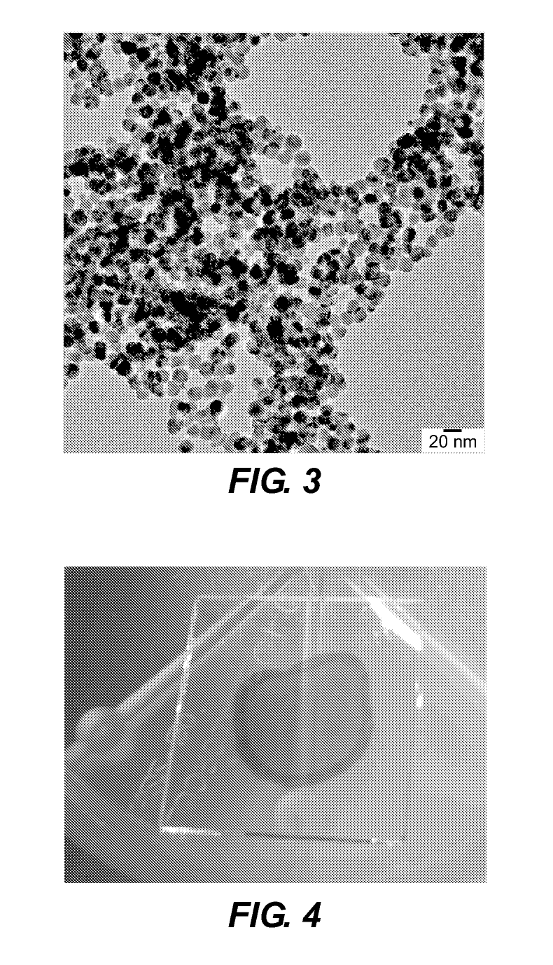

Without any size selective precipitation, TEM analysis revealed the formation of CdSe nanocrystals in a size range from 15 nm to 25 nm (FIG. 3). The absorption spectrum of the unpurified nanocrystal solution reveals a bump at around 720 nm.

After having formed nanocrystals 205, dispersions were created with alcohols as the solvents. More specifically, ˜1 ml of crude solution was added to 3 ml of hexane, and 10 ml of methanol in a centrifuge tube. After centrifuging for a few minutes, the supernatant became clear. It was decanted off and 3-4 ml of pyridine was added. The plug quickly dissolved in the pyridine to produce a clear solution. The solution was heated at 80° C. under continuous stirring for 24 hours in order to exchange the TOPO/HDA/TOP organic ligands 210 for pyridine organic ligands 210.

Some of the excess pyridine was then removed by a vacuum prior to adding ˜12 ml of hexane to the pyridine solution. This solution was then centrifuged, the supernatant decanted, and a mixture of 1-propanol and ethanol was added to the plug in order to get a clear dispersion. Continuous and smooth nanoparticle-based films (see FIG. 4) were obtained upon drop coating the dispersions on clean borosilicate glass. The films were then annealed in a tube furnace (with flowing argon) at 160° C. for 30 minutes to evaporate pyridine ligand 210.

The invention has been described in detail with particular reference to certain preferred embodiments thereof, but it will be understood that variations and modifications can be effected within the spirit and scope of the invention.

### PARTS LIST

100 substrate
105 light emitting diode device
110 p-contact layer
120 p-transport layer
130 intrinsic emitter layer
140 n-transport layer
150 n-contact layer
160 anode
170 cathode
200 semiconductor core
205 inorganic nanoparticle
210 organic ligand

1. A method of making a film of large II-VI nanocrystals, comprising:
a) providing a mixture of column II, column VI chemical precursors, and coordinating solvents selected from amines, phosphines, phosphine oxides, esters, ethers, or combinations thereof; by:
i) injecting under heat a higher molar quantity of column II chemical precursor than column VI chemical precursor; and
ii) injecting a solution including a column VI chemical precursor, or a mixture of column VI and column II chemical precursors with a higher content of column VI precursor to increase the ratio of column VI to column II chemical precursors during the course of the reaction while still heating the mixture until the molar ratio of column VI chemical precursor to column H chemical precursor is in a range of 1 to 10.
b) heating the mixture to grow large nanocrystals functionalized with coordinating ligands;
c) washing the grown nanocrystals to remove the unreacted precursors and excess coordinating solvents; and
d) depositing the large II-VI nanocrystals on a substrate in order to form the film.

2. The method of claim 1 wherein the as-grown coordinating ligands are exchanged with low-boiling point coordinating ligands.

3. The method of claim 2 wherein the film is annealed to remove the low-boiling point coordinating ligands.

4. The method of claim 1 wherein the coordinating solvents include less than 10% by weight of fatty acids.

5. The method of claim 4 wherein the coordinating solvents include less than 5% by weight of fatty acids.

6. The method of claim 1 wherein the coordinating solvents include less than 10% by weight of phosphonic acids.

7. The method of claim 6 wherein the coordinating solvents include less than 5% by weight of phosphonic acids.

8. The method of claim 1 wherein the column II chemical precursors are selected from CdO, CdCO₃, Cd(Ac)₂, CdCl₂, Cd(NO₃)₂, CdSO₄, ZnO, ZnCO₃, Zn(Ac)₂, ZnEt₂, ZnMe₂, Hg₂O, HgCO₃, Hg(Ac)₂, or combinations thereof.

9. The method of claim 1 wherein the large II-VI nanocrystals are binary, ternary, or quaternary.

10. The method of claim 9 wherein the large II-VI nanocrystals are CdSe, ZnSe, ZnTe, CdS, ZnS, CdTe, HgS, ZnₓCd₁₋ₓSe, ZnₓCd₁₋ₓS, ZnₓCd₁₋ₓTe, ZnSeₓS₁₋ₓ, ZnSeₓTe₁₋ₓ, CdSeₓS₁₋ₓ, CdSeₓTe₁₋ₓ, ZnₓCd₁₋ₓSe_{y}Te_{1-y} or ZnₓCd₁₋ₓSe_{y}S_{1-y}.

11. The method of claim 1 wherein the film is formed by spin casting, drop casting, or inkjetting.

12. The method of claim 1 wherein the large nanocrystals have an aspect ratio less than 3:1 and a diameter greater than 10 nanometers.

13. The method of claim 12 wherein the large nanocrystals have an aspect ratio less than 3:1 and a diameter greater than 12 nanometers.

14. The method of claim 13 wherein the semiconductor nanocrystals have an aspect ratio less than 3:1 and a diameter greater than 14 nanometers.

15. The method of claim 1 wherein the film contains less than 5% by volume of organic materials.

16. The method of claim 1 wherein the film includes large nanocrystals having less than 5% by area of the surface functionalized with organic ligands.

17. The method of claim 1 wherein the large nanocrystals are substantially spherical in shape.
